(19) United States
(12) Patent Application Publication
(10) Pub. No.: US 2019/0040177 A1
(43) Pub. Date: Feb. 7, 2019

(54) POLYMER MATERIAL FOR SELF-ASSEMBLY, SELF-ASSEMBLED FILM, METHOD FOR PRODUCING SELF-ASSEMBLED FILM, PATTERN, AND METHOD FOR FORMING PATTERN

(71) Applicant: HORIBA STEC, CO., LTD., Kyoto (JP)

(72) Inventors: Toshiyuki HIMI, Kyoto (JP); Yukio KAWAGUCHI, Kyoto (JP); Terumasa KOSAKA, Kyoto (JP); Kazuhiro HIRAHARA, Kyoto (JP)

(73) Assignee: HORIBA STEC, CO., LTD., Kyoto (JP)

(21) Appl. No.: 16/076,961

(22) PCT Filed: Oct. 21, 2016
(86) PCT No.: PCT/JP2016/081376

§ 371 Date: Aug. 9, 2018

(30) Foreign Application Priority Data
Feb. 19, 2016 (JP) 2016-030499

(51) Int. Cl. C08F 297/02; C08J 5/18; C08J 7/04; H01L 21/027

(52) U.S. Cl. CPC C08F 297/02; C08J 5/18; C08J 2353/00; H01L 21/0271; C08J 7/04

(57) ABSTRACT

Provided is a polymer material for self-assembly, a self-assembled film, a method for producing a self-assembled film, a pattern, and a method for forming a pattern all of which are capable of reducing defects based on faulty microscopic phase separation sites and capable of forming a fine, minute pattern. The polymer material for self-assembly of the present invention contains a multi-block copolymer of a triblock copolymer or more containing a first polymer block containing a structural unit having a specific structure and a second polymer block containing a structural unit having a specific structure. The first polymer block and the second polymer block are coupled with each other.

### FIELD

The present invention relates to a polymer material for self-assembly, a self-assembled film, a method for producing a self-assembled film, a pattern, and a method for forming a pattern and, specifically, to a polymer material for self-assembly, a self-assembled film, a method for producing a self-assembled film, a pattern, and a method for forming a pattern used suitably for resists for producing semiconductors or the like.

### BACKGROUND

In recent years, a fine pattern formation technique using the directed self-assembly (DSA) technique of block copolymers has been gaining the spotlight (refer to Patent Literature 1 to Patent Literature 7, for example) This directed self-assembly technique can produce guide patterns further reduced by several levels compared with guide patterns produced using conventional photolithography techniques (the ArF immersion method, for example). The directed self-assembly technique can form patterns finer than those by electron beam (EB) and extreme ultraviolet (EUV), which are said to be the ultimate fine processing techniques.

### CITATION LIST

### Patent Literature

Patent Literature 1: Japanese Patent Application Laid-open No. 2005-7244 A

Patent Literature 2: Japanese Patent Application Laid-open No. 2005-8701 A

Patent Literature 3: Japanese Patent Application Laid-open No. 2005-8882 A

Patent Literature 4: Japanese Patent Application Laid-open No. 2003-218383 A

Patent Literature 5: Japanese Patent Application Laid-open No. 2010-269304 A

Patent Literature 6: Japanese Patent Application Laid-open No. 2011-129874 A

Patent Literature 7: Japanese Patent Application Laid-open No. 2012-108369 A

### SUMMARY

### Technical Problem

In the fields of photonics crystals, a method for controlling the domain size of organic thin film solar cells, drag delivery polymer micelles, biomaterials, and the like, the formation of patterns such as a fine line/space (hereinafter, also referred to as an “L/S”) and a minute hole (hereinafter, also referred to as a “CH”) of 10 nm or smaller is desired. However, the conventional techniques such as photolithography, electron beam, and extreme ultraviolet are insufficient in the capability of forming microscopic phase separation, produce defects caused by faulty phase structure formation, and have difficulty in the formation of patterns of 10 nm or smaller.

The present invention is made in view of the situation described above and aims to provide a polymer material for self-assembly, a self-assembled film, a method for producing a self-assembled film, a pattern, and a method for forming a pattern all of which are capable of reducing defects based on faulty microscopic phase separation sites and capable of forming a fine, minute pattern.

### Solution to Problem

As a result of earnest study to solve the problem, the inventors of the present invention have found out that a multi-block copolymer of a triblock copolymer or more containing a first polymer block and a second polymer block with a structural unit of a specific structure as a main component that are coupled with each other can maintain polymer properties while holding a fine microscopic phase separation structure, can easily form a pattern of 10 nm or smaller, and can form a fine, minute repeated pattern with reduced defects resulting from faulty microscopic phase separation sites to complete the present invention.

In other words, a polymer material for self-assembly according to the present invention is characterized by including a multi-block copolymer of a triblock copolymer or more containing a first polymer block containing a structural unit represented by the following General Formula (1) and a second polymer block containing a structural unit represented by the following General Formula (2). The first polymer block and the second polymer block are coupled with each other.

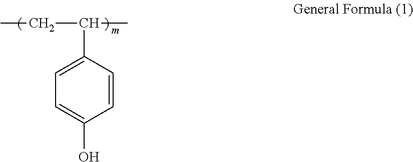

(in General Formula (1), m is an integer of 1 or larger and 1,000 or smaller); and

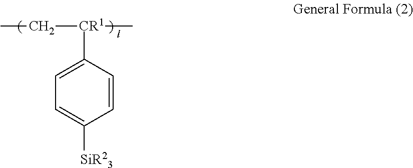

(in General Formula (2), R¹ represents a hydrogen atom and a C₁₋₃ alkyl group, R²s each represent a C₁₋₅ alkyl group; and 1 is an integer of 1 or larger and 1,000 or smaller).

With this polymer material for self-assembly, the first polymer block containing the structural unit represented by General Formula (1) and the second polymer block containing the structural unit represented by General Formula (2) having polarity different from that of the first polymer block are repeated, whereby a repulsive force between the first polymer block and the second polymer block is facilitated. In addition, the structural units represented by General Formula (1) and General Formula (2) each have a functional group at a para-position of a polymer chain, whereby interaction between the first polymer block and the second polymer block improves to increase a χ parameter. In addition, the structural unit represented by General Formula (2) contains a silicon (Si) atom, whereby the interaction between the first polymer block and the second polymer block improves to increase the χ parameter and to improve etching resistance. Owing to these effects, microscopic phase separability improves, defects resulting from faulty microscopic phase separation can be reduced, and a finer repeated pattern can be formed. Consequently, a polymer material for self-assembly that can reduce defects resulting from faulty microscopic phase separation sites and can besides form a fine, minute repeated pattern can be achieved.

In the polymer material for self-assembly according to the present invention, it is preferable that the multi-block copolymer is a triblock copolymer or a tetrablock copolymer.

In the polymer material for self-assembly according to the present invention, it is preferable that the multi-block copolymer is a tetrablock copolymer.

In the polymer material for self-assembly according to the present invention, it is preferable that the multi-block copolymer is copolymerized by living anionic polymerization.

In the polymer material for self-assembly according to the present invention, it is preferable that the multi-block copolymer has a number average molecular weight of 3,000 or higher and 50,000 or lower.

A self-assembled film according to the present invention is characterized by being obtained by using the polymer material for self-assembly described above.

In the self-assembled film according to the present invention, it is preferable that a top coating agent is applied onto a surface thereof.

A method for producing a self-assembled film according to the present invention is characterized by including forming a self-assembled film using the polymer material for self-assembly described above.

In the method for producing a self-assembled film according to the present invention, it is preferable that the self-assembled film is formed within a guide pattern.

In the method for producing a self-assembled film according to the present invention, it is preferable to further include applying a top coating agent onto the self-assembled film.

A pattern according to the present invention is characterized by being formed by etching the self-assembled film described above.

A method for forming a pattern according to the present invention is characterized by including forming a pattern by etching the self-assembled film described above.

The present invention can provide a polymer material for self-assembly that can reduce defects resulting from faulty microscopic phase separation sites and can besides form a fine, minute pattern, and can also provide a self-assembled film, a method for producing a self-assembled film, a pattern, and a method for forming a pattern.

### BRIEF DESCRIPTION OF THE DRAWINGS

FIG. 1 is a diagram of a microdomain structure of a polymer material containing two polymer components.

FIG. 2A is a diagram of a microdomain structure of a spherical structure.

FIG. 2B is a diagram of a microdomain structure of a cylinder structure.

FIG. 2C is a diagram of a microdomain structure of a gyroid structure.

FIG. 2D is a diagram of a microdomain structure of a lamellar structure.

FIG. 3 is a schematic diagram of a molecular chain of a block copolymer.

FIG. 4 is a diagram of examples of multi-block copolymers.

FIG. 5A is a schematic diagram of a lamellar structure as an example of a microscopic phase separation structure that the multi-block copolymer forms.

FIG. 5B is a schematic diagram of a lamellar structure as an example of the microscopic phase separation structure that the multi-block copolymer forms.

FIG. 5C is a schematic diagram of a lamellar structure as an example of the microscopic phase separation structure that the multi-block copolymer forms.

FIG. 5D is a schematic diagram of a lamellar structure as an example of the microscopic phase separation structure that the multi-block copolymer forms.

FIG. 6A is a schematic diagram of a lamellar structure as an example of the microscopic phase separation structure that the multi-block copolymer forms.

FIG. 6B is a schematic diagram of a lamellar structure as an example of the microscopic phase separation structure that the multi-block copolymer forms.

FIG. 6C is a schematic diagram of a lamellar structure as an example of the microscopic phase separation structure that the multi-block copolymer forms.

FIG. 6D is a schematic diagram of a lamellar structure as an example of the microscopic phase separation structure that the multi-block copolymer forms.

FIG. 7 is a diagram of a GPC chart of Tetrablock Copolymer (2).

FIG. 8 is a diagram of a ¹H-NMR measurement result of Tetrablock Copolymer (1).

FIG. 9 is a diagram of a ¹H-NMR measurement result of Tetrablock Copolymer (2).

FIG. 10 is a diagram of a SAXS observation result of a pattern obtained using Triblock Copolymer (2).

### DESCRIPTION OF EMBODIMENTS

The directed self-assembly (hereinafter, also referred to as “DSA”) technique in semiconductors is a technique using the capability of forming microscopic phase separation appearing when two kinds of polymer chains that are incompatible with each other are coupled with each other at one point through copolymerization. In multi-block copolymers such as a diblock copolymer coupled through a covalent bond, when the same polymer component assembles in an inter-molecular manner to cause microscopic phase separation, an interface curvature at the time of molecular assembly changes in accordance with a volume fraction ratio (f) between two polymer components, and a microdomain structure changes.

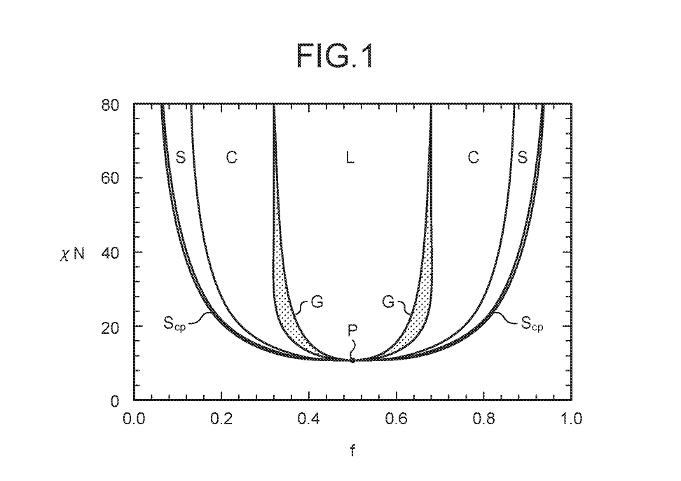

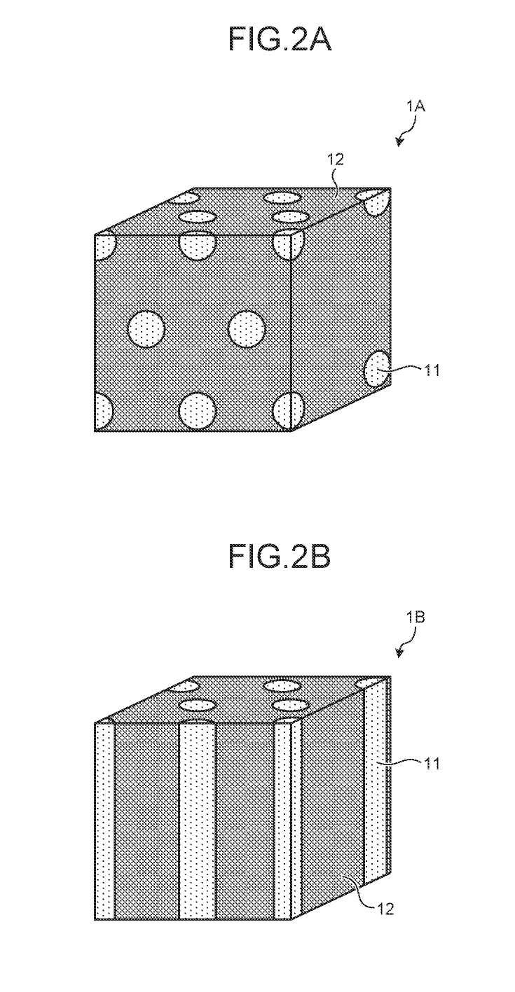

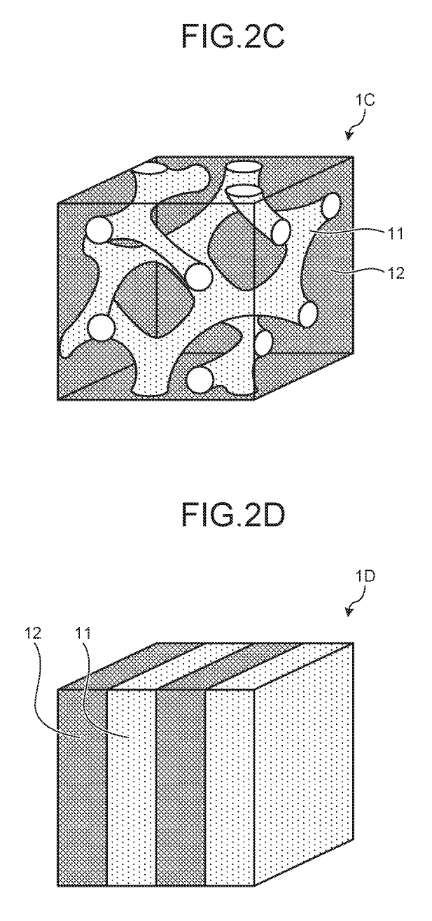

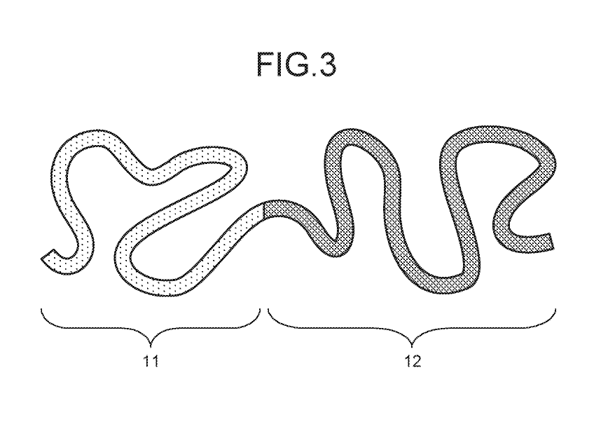

FIG. 1 is a diagram of a microdomain structure of a polymer material containing two polymer components, FIG. 2A is a diagram of a microdomain structure of a spherical structure, FIG. 2B is a diagram of a microdomain structure of a cylinder structure, FIG. 2C is a diagram of a microdomain structure of a gyroid structure, and FIG. 2D is a diagram of a microdomain structure of a lamellar structure. FIG. 3 is a schematic diagram of a molecular chain of a block copolymer. In FIG. 1, the vertical axis indicates a product χ^{N} of an interaction parameter χ and a degree of polymerization N of a polymer, whereas the horizontal axis indicates a composition ratio f between a first component contained in a first polymer block 11 and a second component contained in a second polymer block 12 (the first component/the second component).

As illustrated in FIG. 1, the microdomain structure of the polymer material containing the two polymer components gives orderly morphology including a spherical structure 1A (refer to FIG. 2A), in which the first polymer block 11 is finely dispersed in the second polymer block 12, in an area S in FIG. 1, a cylinder structure 1B (refer to FIG. 2B), in which the first polymer block 11 is linearly dispersed in the second polymer block 12, in an area C in FIG. 1, a gyroid structure 1C (refer to FIG. 2C), in which a plurality of first polymer blocks 11 dispersed in the second polymer block 12 are coupled with each other, in an area G in FIG. 1, and a lamellar structure 1D (refer to FIG. 2D), in which the second polymer block 12 and the first polymer block 11 are lamellarly laminated, in an area L in FIG. 1 as the ratio of the first component increases. A point P in FIG. 1 gives an amorphous state.

In order to obtain a smaller microscopic phase separation structure using the block copolymer, the molecular weight can be reduced while maintaining the compositions of the first polymer block 11 and the second polymer block 12 of the block copolymer. The following Table 1 lists a relation between the molecular weight and the properties including the boiling point, the melting point, and the appearance of polyethylene as an example of the polymer material. As listed in Table 1, polyethylene decreases in molecular weight and boiling point along with a decrease in the degree of polymerization (n). Polyethylene becomes a waxy and fragile solid in an oligomer range with a molecular weight of 3,000 or lower and does not satisfy basic polymer properties such as having a sturdy solid, a high glass transition temperature, and the capability of forming a tough film. Thus, when the molecular weight of the block copolymer is reduced in order to obtain a fine microscopic phase separation structure, the polymer material reaches a region in which microscopic phase separation does not occur after all, becomes a region of molecular weight of oligomer or smaller, loses properties as the polymer material, and cannot obtain properties as a polymer. For this reason, it is described that simply reducing the molecular weights of the first polymer block 11 and the second polymer block 12 cannot obtain a fine microscopic phase separation structure.

TABLE 1

| Degree of | | | | |
|---|---|---|---|---|
| polymerizetion | Molecular | Melting point | Boiling point | |
| (n) | weight | (° C.) | (° C.) | Appearance |
| 1 | 30 | −183 | −88.6 | Gas |
| 10 | 282 | −30 | 174 | Liquid |
| 20 | 562 | 38 | >300 | Waxy |
| 60 | 1,682 | 100 | Decomposed | Waxy solid |
| 100 | 2,802 | 106 | Decomposed | Fragile solid |
| 1,000 | 28,002 | 110 | Decomposed | Sturdy solid |

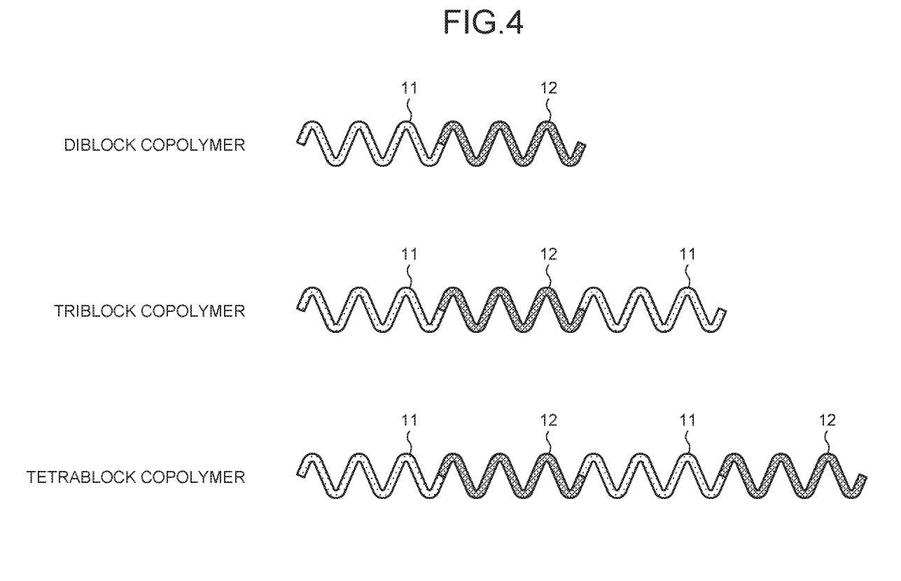

In order to obtain a smaller microscopic phase separation structure while maintaining the properties as the polymer material, a multi-block copolymer in which the two polymer blocks, or the first polymer block 11 and the second polymer block 12, forming the diblock copolymer are repeatedly introduced can be used. FIG. 4 is a diagram of an example of the multi-block copolymer. As illustrated in FIG. 4, the multi-block copolymer includes, for example, the diblock copolymer containing the first polymer block 11 and the second polymer block 12 that are coupled with each other, a triblock copolymer containing the first polymer block 11, the second polymer block 12, and the first polymer block 11 that are coupled with each other, and a tetrablock copolymer containing the first polymer block 11, the second polymer block 12, the first polymer block 11, and the second polymer block 12 that are coupled with each other. The triblock copolymer may be a triblock copolymer containing the first polymer block 11, the second polymer block 12, and a third polymer block other than the first polymer block 11 and the second polymer block 12 that are coupled with each other in addition to the example illustrated in FIG. 4. By thus forming the multi-block copolymer, even when the chain length of the molecular chain of the polymer blocks forming the multi-block copolymer is short, the polymer material for self-assembly can repeat the sequence of the first polymer block 11 and the second polymer block 12 and can thereby increase the sum total of the molecular weight. With this structure, the polymer material for self-assembly can impart the polymer properties even when the molecular weights of the first polymer block 11 and the second polymer block 12 are reduced.

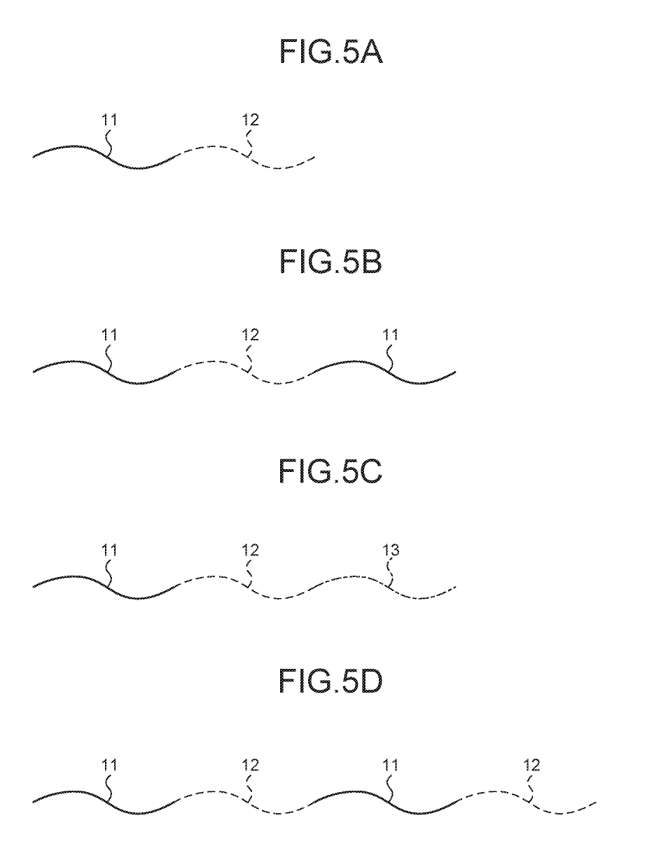

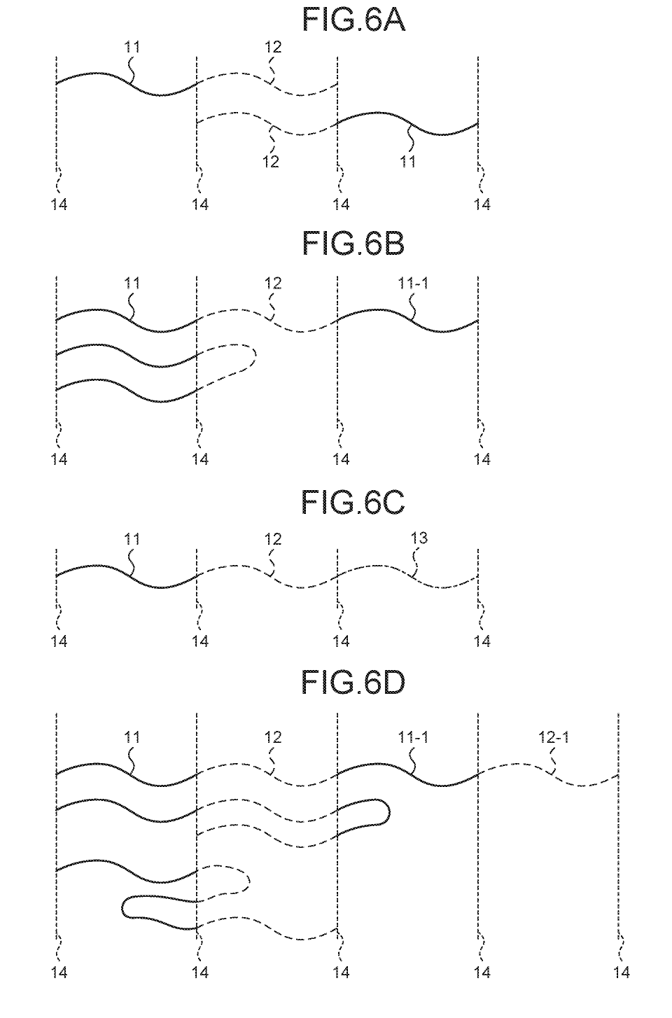

FIG. 5A to FIG. 5D and FIG. 6A to FIG. 6D are schematic diagrams of lamellar structures as an example of the microscopic phase separation structure that the multi-block copolymer forms. As illustrated in FIG. 5A and FIG. 6A, the structure that a block chain formed of the diblock copolymer containing the first polymer block 11 and the second polymer block 12 that are coupled with each other can take in domains is one type that is a structure that passes through an interface 14 of the domains of the first polymer block 11 and the second polymer block 12. As illustrated in FIG. 5B and FIG. 6B, the structure that a block chain formed of the first polymer block 11, the second polymer block 12, and the first polymer block 11 that are coupled with each other of the triblock copolymer can take in domains includes two types including a structure that passes through the interfaces 14 of the domains of the first polymer block 11, the second polymer block 12, and a first polymer block 11-1 and a structure that passes through the interface 14 of the first polymer block 11, folds back within the second polymer block 12, and passes through the domain of the first polymer block 11. As illustrated in FIG. 5C and FIG. 6C, the structure that a block chain formed of the first polymer block 11, the second polymer block 12, and a third polymer block 13 that are coupled with each other of the triblock copolymer can take in domains is one type that is a structure that passes through the interfaces 14 of the domains of the first polymer block 11, the second polymer block 12, and the third polymer block 13.

As illustrated in FIG. 5D and FIG. 6D, the structure that a block chain formed of the first polymer block 11, the second polymer block 12, the first polymer block 11, and a second polymer block 12 that are coupled with each other of the tetrablock copolymer can take in domains includes three types including a structure that passes through the interfaces 14 of the domains of the first polymer block 11, the second polymer block 12, the first polymer block 11-1, and the second polymer block 12-1, a structure that passes through the interfaces 14 of the first polymer block 11 and the second polymer block 12, folds back within the first polymer block 11-1, and reaches the domain of the second polymer block 12, and a structure that passes through the interface 14 of the first polymer block 11, folds back within the second polymer block 12, again folds back within the first polymer block 11-1, and reaches the domain of the second polymer block 12. It is known that the mechanical strength of the block copolymers is higher in a structure in which the polymer chain generally passes through many domains as illustrated in the upper row FIG. 6B and of FIG. 6D (Literature: Macromolecules, Vol. 16, No. 1, 1983). A loop structure illustrated in the lower row of FIG. 6B and FIG. 6D is preferably less. The multi-block copolymer such as the triblock copolymer illustrated in the upper row of FIG. 6B, in which the block chain has many forms that can be taken, shows strength higher than that of the diblock copolymer.

When a diblock copolymer having a lower molecular weight is assumed, the entanglement of the molecular chains of the second polymer block 12 is less in the domain of the second polymer block 12, and accordingly, when a force is applied in the lateral direction, the lamellar structure breaks relatively easily. In contrast, the triblock copolymer and the tetrablock copolymer have the structure that passes through the domains of the first polymer block 11, the second polymer block 12, and the first polymer block 11 or the domains of the first polymer block 11, the second polymer block 12, the first polymer block 11, and the second polymer block 12, and a stronger cohesive force acts. Under these circumstances, the triblock copolymer and the tetrablock copolymer can form a smaller microscopic phase separation structure than the diblock copolymer and can thereby impart more excellent polymer properties.

In the DSA technique, fine processing that is difficult by the conventional photolithography technique, electron beam lithography (EB), and extreme ultraviolet lithography (EUV) is studied. However, a styrene-methyl methacrylate-based diblock copolymer used in the conventional DSA technique does not form any microscopic phase separation structure from around 14 nm and has difficulty in forming a line/space and a hole of 10 nm or smaller. Although diblock copolymers formed of block chains other than styrene-methyl methacrylate are studied, most lose the capability of forming microscopic phase separation in the region of around 10 nm or smaller and may fail to obtain a desired phase structure or produce defects caused by faulty phase structure formation.

The inventors of the present invention paid attention to the characteristics of the polymer material and, as a result of earnest study to solve the problems, paid attention to the capability of solving the problems by changing the individual block chains of the diblock copolymer into a multi-block copolymer. In other words, the inventors of the present invention have found out that using a multi-block copolymer of a triblock copolymer or more containing the first polymer block 11 containing a first structural unit and the second polymer block 12 containing a second structural unit can maintain the polymer properties while holding a fine microscopic phase separation structure. In addition, the inventors of the present invention have found out that using an ABA type (or an ABC type) triblock copolymer having an increased entire molecular weight by adding the first polymer block 11 (or a third polymer block 13) as a new third component to the multi-block copolymer or an ABAB type (or an ABCA type or the like) tetrablock copolymer obtained by further adding the third polymer block and a fourth polymer block can maintain the polymer properties while holding a finer microscopic phase separation structure. The inventors of the present invention have found out that the multi-block copolymers can easily form the L/S and the CH of 10 nm or smaller and can form a fine, minute repeated pattern with reduced defects based on faulty microscopic phase separation sites to complete the present invention.

The following describes an embodiment of the present invention in detail.

The polymer material for self-assembly according to the present invention contains a multi-block copolymer of a triblock copolymer or more containing a first polymer block with a structural unit containing the following General Formula (1) as a main component and a second polymer block with a structural unit represented by the following General Formula (2) as a main component that are coupled with each other through copolymerization:

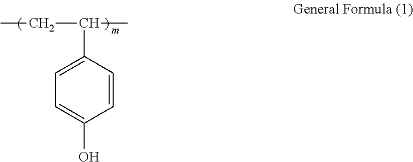

(in General Formula (1), m is an integer of 1 or larger and 1,000 or smaller); and

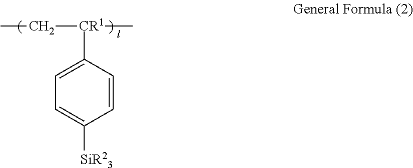

(in General Formula (2), R¹ represents a hydrogen atom and a C₁₋₃ alkyl group, R²s each represent a C₁₋₅ alkyl group; and 1 is an integer of 1 or larger and 1,000 or smaller).

With this polymer material for self-assembly, the first polymer block containing the structural unit represented by General Formula (1) and the second polymer block containing the structural unit represented by General Formula (2) having polarity different from that of the first polymer block are repeated, whereby a mutual repulsive force is facilitated. In addition, the structural units represented by General Formula (1) and General Formula (2) each have a functional group at a para-position of a polymer chain, whereby interaction between the first polymer block and the second polymer block improves to increase a χ parameter. In addition, the structural unit represented by General Formula (2) contains a silicon (Si) atom, whereby the interaction between the first polymer block and the second polymer block improves to increase the χ parameter and to improve etching resistance. Owing to these effects, microscopic phase separability improves, defects resulting from faulty microscopic phase separation can be reduced, and a finer repeated pattern can be formed. Consequently, the polymer material for self-assembly can achieve a polymer material for self-assembly that can reduce defects resulting from faulty microscopic phase separation sites and can besides form a fine, minute repeated pattern.

R¹ in General Formula (2) is not limited to a particular group so long as it is a hydrogen atom and a C₁₋₃ alkyl group. Examples of the C₁₋₃ alkyl group include a methyl group, an ethyl group, an n-propyl group, and an iso-propyl group. Among these, R¹ is preferably a hydrogen atom or a methyl group and more preferably a hydrogen atom in view of being capable of reducing the defects resulting from the faulty microscopic phase separation sites and besides capable of forming the fine, minute repeated pattern.

R² in General Formula (2) is not limited to a particular group so long as it is a C₁₋₅ alkyl group. Examples of the C₁₋₅ alkyl group include a methyl group, an ethyl group, an n-propyl group, an iso-propyl group, an n-butyl group, an s-butyl group, a t-butyl group, an n-pentyl group, and a neopentyl group. The three R²s in General Formula (2) may be the same as or different from each other. Among these, R² is preferably a methyl group, an ethyl group, an n-propyl group, or an iso-propyl group, more preferably a methyl group or an ethyl group, and further preferably a methyl group in view of being capable of reducing the defects resulting from the faulty microscopic phase separation sites and besides capable of forming the fine, minute repeated pattern.

For the first polymer block of the multi-block copolymer, a first polymer block A obtained by repeatedly polymerizing the same structural unit represented by General Formula (1) or a first polymer block B obtained by repeatedly polymerizing the structural unit represented by General Formula (1) and a structural unit different from General Formula (1) can be used. For the second polymer block of the multi-block copolymer, a second polymer block C obtained by repeatedly polymerizing the same structural unit represented by General Formula (2) or a second polymer block D obtained by repeatedly polymerizing the structural unit represented by General Formula (2) and a structural unit different from General Formula (2) can be used. For the triblock copolymer, one in which the polymer blocks A-D are arbitrarily arranged such as ACA, ACB, ADA, or ADB can be used. Among these, the triblock copolymer preferably has an arrangement of ACA or ADA in view of being further capable of reducing the defects resulting from the faulty microscopic phase separation sites and besides capable of forming the fine, minute repeated pattern. For the tetrablock copolymer, any arrangement such as ACAC, ACBC, ADAD, or ADBC can be used. Among these, the tetrablock copolymer is preferably ACAC or ADAD in view of being capable of reducing the defects based on the faulty microscopic phase separation sites and besides capable of forming the fine, minute repeated pattern.

For the multi-block copolymer, a triblock copolymer containing the first polymer block containing the structural unit represented by General Formula (1) and the second polymer block containing the structural unit represented by General Formula (2) may be used, or a tetrablock copolymer may be used. For the multi-block copolymer, a multi-block copolymer of a pentablock copolymer or more formed of a plurality of first polymer blocks and second polymer blocks that are coupled with each other through copolymerization can be used. Among these, the multi-block copolymer is preferably the triblock copolymer or the tetrablock copolymer and further preferably the tetrablock copolymer in view of being capable of reducing the defects resulting from the faulty microscopic phase separation sites and besides capable of forming the fine, minute repeated pattern. The ratio of the structural units when the triblock copolymer and the tetrablock copolymer are used as polymer compounds is not limited to a particular ratio, and the ratio can be selected as appropriate in accordance with the type of the microdomain structure formed by self-assembly.

The ratio of the structural units of the multi-block copolymer is, in terms of a composition ratio (m:l) between the structural unit represented by General Formula (1) (m) and the structural unit represented by General Formula (2) (l), preferably in the range of m:l=8:2 to 2:8 in view of improving the pattern uniformity and regularity of the microdomain structure formed by self-assembly. When the lamellar structure is formed by self-assembly, for example, the ratio (m:l) between the structural unit represented by General Formula (1) (m) and the structural unit represented by General Formula (2) (l) is preferably in the range of m:l=4:6 to 6:4 and more preferably m:l=5:5 in view of improving the pattern uniformity and regularity of the microdomain structure formed by self-assembly. When the cylinder structure is formed by self-assembly, the ratio (m:l) between the structural unit represented by General Formula (1) (m) and the structural unit represented by General Formula (2) (l) is preferably in the range of m:l=3:7 to 7:3 in view of improving the pattern uniformity and regularity of the microdomain structure formed by self-assembly. In this case, a structural unit of the smaller ratio forms an internal film of the cylinder structure.

The average number of molecules of each of the first polymer block and the second polymer block is preferably 10 or larger and 1,000 or smaller, more preferably 15 or larger and 100 or smaller, further preferably 20 or larger and 50 or smaller, and still further preferably 25 or larger and 40 or smaller in view of improving the pattern uniformity and regularity of the microdomain structure formed by self-assembly.

The number average molecular weight (Mn) of the multi-block copolymer is preferably 3,000 or higher, more preferably 5,000 or higher, and further preferably 6,000 or higher and preferably 100,000 or lower, more preferably 50,000 or lower, and further preferably 20,000 or lower in view of improving the pattern uniformity and regularity of the microdomain structure formed by self-assembly. When the number average molecular weight (Mn) is 3,000 or higher, self-assembly proceeds, and a self-assembled film in which the microdomain structure is formed is obtained. When the number average molecular weight (Mn) is 50,000 or lower, hydrogen bonding of hydrophilic groups of the polymer compound moderately acts, self-assembly occurs without the shortage of a χ parameter among the block copolymers, and the microdomain structure is formed, whereby the pattern size can be easily 10 nm or smaller. The polymer material for self-assembly according to the present invention contains the multi-block copolymer with a number average molecular weight (Mn) of 10,000 or lower within the range that produces the advantageous effects of the present invention.

The polydispersity index (PDI: Mw/Mn=PDI) of the multi-block copolymer is preferably 1.0 or larger and more preferably 1.02 or larger and preferably 1.1 or smaller and more preferably 1.06 or smaller in view of being capable of reducing the defects resulting from the faulty microscopic phase separation sites and besides capable of forming the fine, minute repeated pattern. When the PDI is 1.0 or larger and 1.1 or smaller, the mixing of a low molecular weight polymer and a high molecular weight polymer hardly occurs, and the pattern uniformity and regularity of the microdomain structure formed by self-assembly improve.

The number average molecular weight (Mn) and the PDI are measured by gel permeation chromatography (GPC) in terms of polystyrene as a standard substance. The weight average molecular weight by GPC is calculated using a GPC measuring apparatus (product name: HLC-8220GPC manufactured by Tosoh Corporation), a column (product name: GPC Column TSKgel Super HZ2000 HZ3000 manufactured by Tosoh Corporation), and a mobile phase (THF) by measuring at a column temperature of 30° C., using the calibration curve of the standard polystyrene, for example.

The composition ratio of the multi-block copolymer can be determined by the nuclear magnetic resonance (NMR) method. The composition ratio by the NMR method can be measured under the condition of an NMR measuring apparatus (product name: “ADVANCE III HD Nano-Bay Digital NMR Apparatus” manufactured by Bruker, analysis software: Bruker TopSpin (registered trademark) 3.2, frequency: 500 MHz), a temperature of 25° C., a solvent of (CDCl₃), internal standard: tetramethylsilane (TMS), and an integrated number of times of 128, for example.

The multi-block copolymer is preferably a multi-block copolymer of the first polymer block with the structural unit represented by General Formula (1) as the main component and the second polymer block with the structural unit represented by General Formula (2) as the main component that are copolymerized by living anionic polymerization. A polymer compound is copolymerized by living anionic polymerization, whereby the PDI can be extremely narrowed, and a polymer compound having a desired number average molecular weight can be obtained with high precision. With this copolymerization, the pattern uniformity and regularity of the microdomain structure formed by self-assembly can be improved.

A method for producing the polymer compound, which is the multi-block copolymer, is not limited to a particular method so long as it can copolymerize the first polymer block with the structural unit represented by General Formula (1) as the main component and the second polymer block with the structural unit represented by General Formula (2) as the main component. Examples of the method of polymerization to obtain the polymer compound include living anionic polymerization, living cationic polymerization, living radical polymerization, and coordinated polymerization using an organometallic catalyst. Among these, living anionic polymerization is preferable, which enables living polymerization with less deactivation of polymerization and side reactions.

In living anionic polymerization, a monomer for polymerization subjected to deoxidation and dehydration treatment and an organic solvent are used. Examples of the organic solvent include hexane, cyclohexane, toluene, benzene, diethyl ether, and tetrahydrofuran. In living anionic polymerization, an anionic species is added to any of these organic solvents in a necessary amount, and the monomer is then added thereto as needed, thereby performing polymerization. Examples of the anionic species include organic metals such as alkyl lithium, alkyl magnesium halide, sodium naphthalene, and alkylated lanthanoid compounds. According to the present invention, a substituted polystyrene is copolymerized as the monomer, and the anionic species is preferably s-butyl lithium or butyl magnesium chloride among these. The polymerization temperature of living anionic polymerization is preferably within the range of −100° C. or higher and 50° C. or lower and more preferably −70° C. or higher and 40° C. or lower in view of facilitating the control of polymerization.

A method for producing the multi-block copolymer performs block copolymerization on a monomer of a substituted styrene with a protected phenolic hydroxy group such as p-(1-ethoxyethyl)styrene by living anionic polymerization on the above conditions to synthesize the block copolymer, for example. This block copolymer can deprotect the phenolic hydroxy group of the obtained polymer compound using an acid catalyst such as oxalic acid. Examples of a protecting group for the phenolic hydroxy group during polymerization include a t-butyl group and a trialkylsilyl group in addition to p-(1-ethoxyethyl)styrene. When another monomer having an ether moiety or an ester moiety is copolymerized in the polymer compound, selective deprotection is performed by the adjustment of the acidity during the deprotection reaction and a deprotection reaction under alkaline conditions, whereby the phenolic hydroxy group can be obtained.

The self-assembled film according to the present invention can be obtained by dissolving the polymer material for self-assembly in an organic solvent and applying it. The organic solvent dissolving the polymer material for self-assembly is not limited to a particular organic solvent so long as it can obtain the self-assembled film; examples thereof include butyl acetate, amyl acetate, cyclohexyl acetate, 3-methoxybutyl acetate, methyl ethyl ketone, methyl amyl ketone, cyclohexanone, cyclopentanone, 3-ethoxyethyl propionate, 3-ethoxymethyl propionate, 3-methoxymethyl propionate, methyl acetoacetate, ethyl acetoacetate, diacetone alcohol, methyl pyruvate, ethyl pyruvate, propylene glycol monomethyl ether, propylene glycol monoethyl ether, propylene glycol monomethyl ether propionate, propylene glycol monoethyl ether propionate, ethylene glycol monomethyl ether, ethylene glycol monoethyl ether, diethylene glycol monomethyl ether, diethylene glycol monoethyl ether, 3-methyl-3-methoxy butanol, N-methyl pyrrolidone, dimethylsulfoxide, γ-butyrolactone, propylene glycol methyl ether acetate, propylene glycol ethyl ether acetate, propylene glycol propyl ether acetate, methyl lactate, ethyl lactate, propyl lactate, and tetramethylene sulfone. These solvents may be used singly, or two or more of them may be used in combination.

The organic solvent dissolving the polymer material for self-assembly is preferably a propylene glycol alkyl ether acetate or an alkyl lactate ester. Examples of the propylene glycol alkyl ether acetate include one having a C₁₋₄ alkyl group. Examples of the alkyl group include a methyl group, an ethyl group, a propyl group, and a butyl group. Among these, a methyl group and an ethyl group are preferable. The propylene glycol alkyl ether acetate includes three isomers depending on the combination of substitution positions including a 1,2-substitution product and a 1,3-substitution product; these isomers may be used singly, or two or more of the isomers may be used in combination.

Examples of the alkyl lactate ester include one having a C₁₋₄ alkyl group. Examples of the alkyl group include a methyl group, an ethyl group, a propyl group, and a butyl group. Among these, a methyl group and an ethyl group are preferable.

Concerning the concentration of the organic solvent, when the propylene glycol alkyl ether acetate is used, for example, the propylene glycol alkyl ether acetate is preferably 50% by mass or more relative to the entire mass of the organic solvent. When the alkyl lactate ester is used, it is preferably 50% by mass or more relative to the entire mass of the organic solvent. When a mixed solvent of the propylene glycol alkyl ether acetate and the alkyl lactate ester is used as the organic solvent, the total amount of the mixed solvent is preferably 50% by mass or more relative to the entire mass of the organic solvent. When this mixed solvent is used, the ratio is preferably as follows: the propylene glycol alkyl ether acetate is 60% by mass or higher and 95% by mass or lower, whereas the alkyl lactate ester is 5% by mass or higher and 40% by mass or lower. When the propylene glycol alkyl ether acetate is 60% by mass or higher, the applicability of the polymer material for self-assembly is favorable. When the propylene glycol alkyl ether acetate is 95% by mass or lower, the solubility of the polymer material for self-assembly improves.

The concentration of the solution of the organic solvent of the polymer material for self-assembly is not limited to a particular concentration so long as it can obtain the self-assembled film by a conventionally known method of film formation; the organic solvent is preferably 5,000 parts by mass or more and 50,000 parts by mass or less and more preferably 7,000 parts by mass or more and 30,000 parts by mass or less relative to 100 parts by mass of the solid content of the polymer material for self-assembly, for example.

A method for applying the polymer material for self-assembly is not limited to a particular method so long as it can obtain the self-assembled film; examples thereof include spin coating, immersion, flexographic printing, inkjet printing, spraying, potting, and screen printing.

For the self-assembled film, a top coating agent may be applied onto the self-assembled film. With this application, the self-assembled film is sealed and protected, and the self-assembled film improves in handleability and weatherability. Examples of the top coating agent include polyester-based top coating agents, polyamide-based top coating agents, polyurethane-based top coating agents, epoxy-based top coating agents, phenol-based top coating agents, (meth)acrylic-based top coating agents, polyvinyl acetate-based top coating agents, polyolefin-based top coating agents such as polyethylene-based top coating agents and polypropylene-based top coating agents, and cellulose-based top coating agents. The coating amount (in terms of solid content) of the top coating agent is preferably 3 g/m² or more and 7 g/m² or less. The top coating agent can be applied onto the self-assembled film by a conventionally known method of application. For the self-assembled film, an undercoating agent can be applied onto the self-assembled film. For the undercoating agent, conventionally known various kinds of undercoating agents can be used.

The self-assembled film may be formed within a guide pattern. In this case, the self-assembled film can be formed by applying a solution of the polymer material for a self-assembled film onto a guide pattern-equipped silicon substrate or the like, for example. Annealing treatment at 200° C. or higher and 300° C. or lower for 5 minutes or longer and 1 hour or shorter gives a pattern of a self-assembled microdomain structure on the silicon substrate. The obtained pattern of the microdomain structure is etched with an oxygen plasma gas, whereby an L/S pattern and a CH pattern with a half pitch (hp) of 10 nm or smaller can be obtained.

For the multi-block copolymer, a cohesive force can be evaluated by transmission electron microscopic (TEM) observation and small-angle X-ray scattering (SAXS) measurement. An evaluation sample of the cohesive force can be prepared by preparing a sample film of 50 mg of the multi-block copolymer, dissolving the prepared sample in 1 g of additive-free THF and moving the sample to a Teflon petri dish, and casting the sample in the Teflon petri dish for 10 days and drying the sample in a vacuum, for example.

In the TEM observation, the sample film is first cut into appropriate sizes and is put in an embedding mold, and an epoxy resin is then poured thereinto, which is left at rest at 60° C. for 12 hours to cure the epoxy resin, whereby embedding treatment is performed. The sample film subjected to the embedding treatment is cut into a section with a thickness of about 50 nm using a microtome. The section is then gathered on a Cu grid, is dyed with Cs₂CO₃, and is then observed with a transmission electron microscope, whereby the hp can be measured.

In the SAXS measurement, powder of the block copolymer is subjected to heat treatment on a heat-resistant film, for example, and microscopic phase separability measurement in a bulk state can be performed using a small-angle X-ray scattering (SAXS) analyzer (ultrafine periodic structure analysis system Nano-Viewer AXIS IV manufactured by Rigaku Corporation). In this microscopic phase separability measurement, X-rays are made incident on the sample film of the block copolymer, and the angle dependence of scattering appearing on the smaller angle side is measured by an imaging plate for 60 minutes, for example. In measured data processing, background correction such as air scattering is performed to calculate q/nm-l, Fourier transformation analysis is performed, and the value of half pitch (hp) of the self-assembled film, which is half the identity period (d) of the average repeated pattern size width of the microdomain structure by the self-assembly of the block copolymer, can be measured.

As described above, according to the polymer material for self-assembly according to the present invention, the first polymer block containing the structural unit represented by General Formula (1) and the second polymer block containing the structural unit represented by General Formula (2) having polarity different from that of the first polymer block are repeated, whereby the repulsive force between the first polymer block and the second polymer block is facilitated. In addition, the structural units represented by General Formula (1) and General Formula (2) each have the functional group at the para-position of the polymer chain, whereby the interaction between the first polymer block and the second polymer block improves to increase the χ parameter. In addition, the structural unit represented by General Formula (2) contains a silicon (Si) atom, whereby the interaction between the first polymer block and the second polymer block improves to increase the χ parameter and to improve etching resistance. Owing to these effects, microscopic phase separability improves, defects resulting from faulty microscopic phase separation can be reduced, and a finer repeated pattern can be formed. Consequently, a polymer material for self-assembly that can reduce defects resulting from faulty microscopic phase separation sites and can besides form a fine, minute repeated pattern can be achieved. The organic solvent solution of the obtained polymer material for self-assembly is applied onto a silicon substrate or the like, and baking treatment and annealing treatment are then performed, whereby a fine L/S pattern (with an hp of 10 nm or smaller, for example) of the microdomain structure formed by self-assembly can be obtained. With this achievement, the polymer material for self-assembly according to the present invention can form the L/S pattern with an hp of 10 nm or smaller, which is difficult by a conventional ArF excimer laser and EUV lithography, can thereby be used suitably as an etching mask material for producing semiconductors or the like, and can be extended into various fields such as applications to photonics crystals, usage as a method for controlling the domain size of organic thin film solar cells, drug delivery polymer micelles, and biomaterials.

### EXAMPLES

The following describes examples and a comparative example performed to clarify the advantageous effects of the present invention. The following examples and comparative example do not limit the present invention at all.

### First Example: Synthesis of Tetrablock Copolymer

A 5-L anionic polymerization reactor was dried under reduced pressure, and 4,500 g of a tetrahydrofuran (THF) solution subjected to distillation dehydration treatment with metallic sodium and anthracene was injected thereinto under reduced pressure and was cooled to −70° C. Next, 9.09 ml of s-butyl lithium (a cyclohexane solution: 2.03 mol/L) was injected into the cooled THF solution. Subsequently, 35.9 g of 4-ethoxyethoxy styrene subjected to distillation purification treatment was added dropwise thereto while adjusting a dropping speed so as not to make the internal temperature of the reaction solution −60° C. or higher, and the reaction solution was reacted for additional 30 minutes after the end of the dropwise addition. Next, 39.1 g of 4-trimethylsilyl styrene subjected to distillation dehydration treatment was further injected dropwise thereinto, and the reaction solution was reacted for 30 minutes. After that, 35.9 g of 4-ethoxyethoxy styrene and 39.1 g of 4-trimethylsilyl styrene were successively added dropwise thereto to continuously perform a polymerization reaction. After that, 30 g of methanol was charged thereinto to stop the polymerization reaction, and the reaction solution was concentrated to obtain 150 g of Tetrablock Copolymer (1).

Next, 50 g of the obtained Tetrablock Copolymer (1) was dissolved in 300 g of THF and was injected into a 1-L reaction vessel, 175 g of methanol and 1 g of oxalic acid were then added thereto, and a deprotection reaction was performed in a nitrogen atmosphere at 40° C. for 20 hours. Next, the reaction solution was cooled to near room temperature, and 2 g of pyridine was then added thereto to perform a neutralization reaction. Next, the obtained reaction solution was concentrated under reduced pressure, and 100 g of THF and 100 g of acetone were then injected thereinto to redissolve the tetrablock copolymer after deprotection. Next, the solution of the tetrablock copolymer subjected to deprotection was added to 4.5 L of ultrapure water, and Tetrablock Copolymer (2) was precipitated and washed. Next, the solid component was filtered out with a filter and was then dried under reduced pressure at 50° C. for 20 hours to obtain 45 g of a white powdery solid of Tetrablock Copolymer (2).

<Measurement of Number Average Molecular Weight (Mn) and Polydispersity Index (PDI) of Tetrablock Copolymer (2)>

The number average molecular weight and the polydispersity index of the obtained Tetrablock Copolymer (2) were measured by gel permeation chromatography (GPC). The measurement conditions are described below:

GPC measurement apparatus: product name: “HLC-8220GPC” manufactured by Tosoh Corporation

Column: product name: “GPC Column TSKgel Super HZ2000 HZ3000” manufactured by Tosoh Corporation

Mobile phase: THF

Column temperature: 30° C.

Standard substance: polystyrene

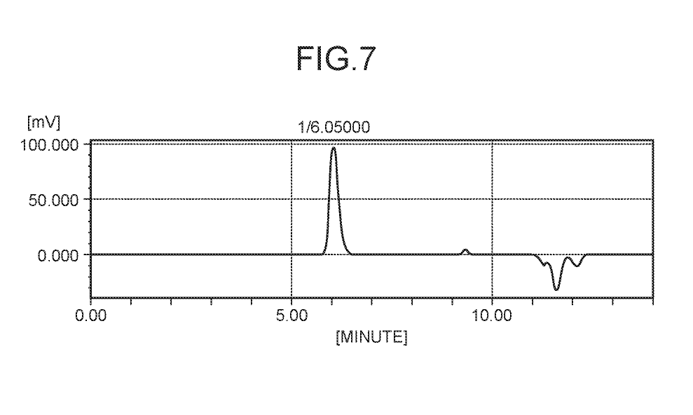

FIG. 7 is a diagram of a GPC chart of Tetrablock Copolymer (2). As illustrated in FIG. 7, as a result of the measurement of GPC in terms of the standard polystyrene, the Mn of the obtained Tetrablock Copolymer (2) was 13,000 g/mol, and the PDI thereof was 1.14.

<Measurement of Composition Ratio of Tetrablock Copolymer (2)>

The composition ratio of the obtained Tetrablock Copolymer (2) was measured by nuclear magnetic resonance (NMR) spectroscopy (H-NMR). The measurement conditions are described below:

NMR measuring apparatus: product name “ADVANCEIII HD Nano-Bay Digital NMR Apparatus manufactured by Bruker, analysis software: Bruker TopSpin (registered trademark) 3.2”

Frequency: 500 MHz

Temperature: 25° C.

Solvent: CDCl₃

Internal standard: tetramethylsilane (TMS)

Integrated number of times: 128

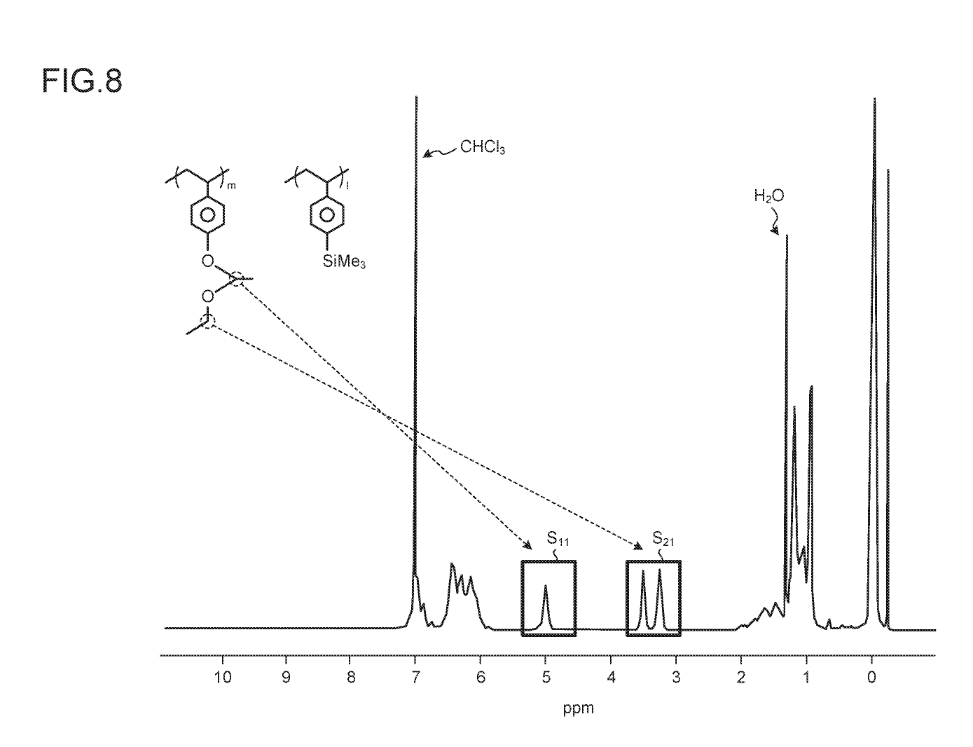

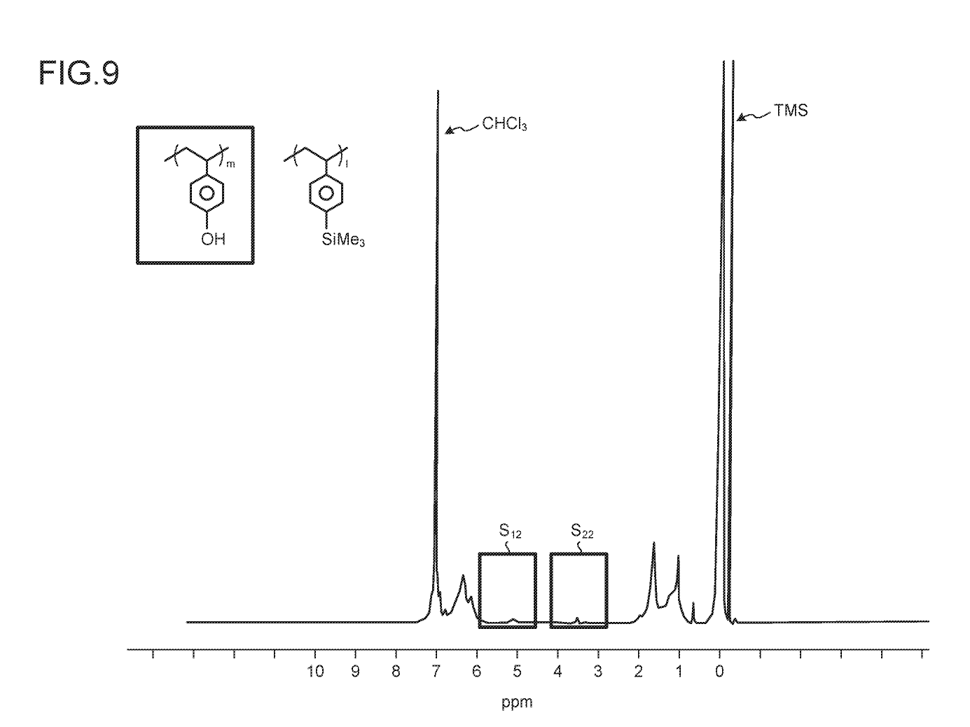

FIG. 8 is a diagram of a ¹H-NMR measurement result of Tetrablock Copolymer (1). FIG. 9 is a diagram of a ¹H-NMR measurement result of Tetrablock Copolymer (2). As illustrated in FIG. 8 and FIG. 9, the ¹H-NMR measurement results revealed signals (6.0 ppm to 7.0 ppm) originated from a benzene ring, signals (6.2 ppm to 7.2 ppm) originated from a methine group and a methylene group, and a signal (8.7 ppm to 9.2 ppm) originated from a hydroxy group. It was revealed that signals S₁₁ and S₂₁ (around 3 ppm to 4 ppm and 5 ppm) originated from a methoxymethyl group not subjected to deprotection disappeared after deprotection (signals S₁₂ and S₂₂). In addition, it was revealed from the area ratio of the signals that the composition ratio of Tetrablock Copolymer (2) was 4-hydroxy styrene:4-trimethylsilyl styrene=50:50.

In the SAXS measurement, powder of the block copolymer was subjected to heat treatment on a heat-resistant film, and microscopic phase separability measurement in a bulk state was performed using a small-angle X-ray scattering (SAXS) analyzer (ultrafine periodic structure analysis system Nano-Viewer AXIS IV manufactured by Rigaku Corporation). X-rays were made incident on the sample film of the block copolymer, and the angle dependence of scattering appearing on the smaller angle side was measured by an imaging plate for 60 minutes. In measured data processing, background correction such as air scattering was performed to calculate q/nm-1, Fourier transformation analysis was performed, and the value of half pitch (hp) of the self-assembled film, which was half the identity period (d) of the average repeated pattern size width of the microdomain structure by the self-assembly of the block copolymer, was measured.

Consequently, the identity period (d) was 11.82 nm, and the half pitch (hp) was 5.9 nm.

### Second Example: Synthesis of Triblock Copolymer

A 5-L anionic polymerization reactor was dried under reduced pressure, and 4,500 g of a tetrahydrofuran (THF) solution subjected to distillation dehydration treatment with metallic sodium and benzophenone was injected thereinto under reduced pressure and was cooled to −70° C. Next, 11.5 ml of s-butyl lithium (a cyclohexane solution: 2.03 mol/L) was injected into the cooled THF solution, 33.9 g of 4-ethoxyethoxy styrene subjected to distillation purification treatment was injected dropwise thereinto while adjusting a dropping speed so as not to make the internal temperature of the reaction solution −60° C. or higher, and the reaction solution was reacted for additional 30 minutes after the end of the dropwise addition. Next, 74.0 g of 4-trimethylsilyl styrene was injected dropwise thereinto, and the reaction solution was reacted for 30 minutes. After that, 33.9 g of 4-ethoxyethoxy styrene was again added dropwise thereto to polymerize Triblock Copolymer (I). Next, 30 g of methanol was charged thereinto to stop the reaction, and the reaction solution was concentrated to obtain 142 g of Triblock Copolymer (1). Next, 100 g of THF and 335 g of acetone were injected into 50 g of Triblock Copolymer (1) to redissolve Triblock Copolymer (1), which was then added to 4.5 L of ultrapure water, and Triblock Copolymer (1) was precipitated and washed. Next, the solid component was filtered out with a filter and was then dried under reduced pressure at 50° C. for 20 hours to obtain 48.0 g of a white powdery solid of Triblock Copolymer (1).

Next, 48 g of the obtained Triblock Copolymer (1) was dissolved in 288 g of THF and was injected into a 1-L reaction vessel, 168 g of methanol and 0.96 g of oxalic acid were then added thereto, and a deprotection reaction was performed in a nitrogen atmosphere at 40° C. for 20 hours. Next, the reaction solution was cooled to near room temperature, and 1.92 g of pyridine was then added thereto to perform a neutralization reaction. Next, the obtained deprotection reaction solution was concentrated under reduced pressure, and 96 g of THF and 96 g of acetone were then injected thereinto to redissolve Triblock Copolymer (2) subjected to deprotection. Next, the solution of Triblock Copolymer (2) subjected to deprotection was added to 4.5 L of ultrapure water, and Triblock Copolymer (2) was precipitated and washed. Next, the solid component was filtered out with a filter and was then dried under reduced pressure at 50° C. for 20 hours to obtain 45.0 g of a white powdery solid of Triblock Copolymer (2).

Using the obtained Triblock Copolymer (2), the composition ratio, the Mn, and the PDI of Triblock Copolymer (2) were measured by the methods of measurement described above. The measurement results are described below and are listed in the following Table 2:
Composition ratio of Triblock Copolymer (2) 4-hydroxy styrene: 4-trimethylsilyl styrene=50:50
Mn=7,000 g/mol
PDI=1.11

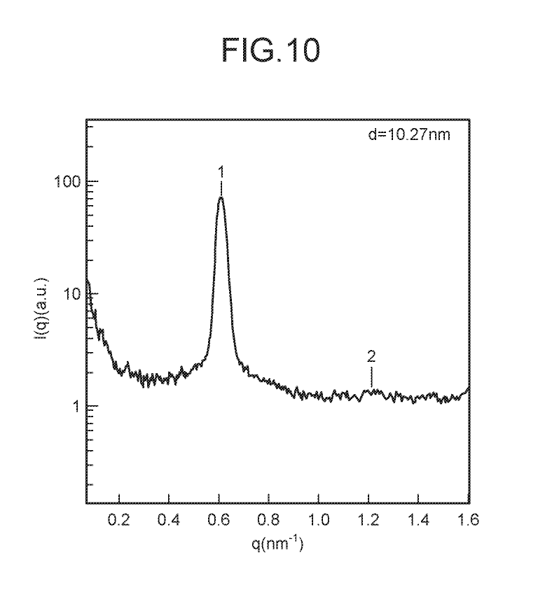

Next, the identity period (d) and the hp of a pattern prepared by the method described above were measured. FIG. 10 is a diagram of a SAXS observation result of a pattern obtained using Triblock Copolymer (2). As illustrated in FIG. 11, the identity period (d) was 10.27 nm, and the hp was 5.1. The measurement results are listed in the following Table 2.

### First Comparative Example: Synthesis of Diblock Copolymer

A 5-L anionic polymerization reactor was dried under reduced pressure, and 4,500 g of a tetrahydrofuran (THF) solution subjected to distillation dehydration treatment with metallic sodium and benzophenone was injected thereinto under reduced pressure and was cooled to −70° C. Next, 25.5 ml of s-butyl lithium (a cyclohexane solution: 2.03 mol/L) was injected into the cooled THF solution, 76.7 g of 4-trimethylsilyl styrene subjected to distillation purification treatment was added dropwise thereto while adjusting a dropping speed so as not to make the internal temperature of the reaction solution −60° C. or higher, and the reaction solution was reacted for 30 minutes after the end of the dropwise addition. Next, 127.4 g of 4-ethoxyethoxy styrene was injected dropwise thereinto, and the reaction solution was reacted for 30 minutes to polymerize Diblock Copolymer (I). Next, 30 g of methanol was charged thereinto to stop the reaction, and the reaction solution was then concentrated under reduced pressure. Next, 335 g of acetone was injected thereinto to redissolve Diblock Copolymer (1), which was then added to 18.5 L of ultrapure water, and Diblock Copolymer (1) was precipitated and washed. Next, the solid component was filtered out with a filter and was then dried under reduced pressure at 50° C. for 20 hours to obtain 204.1 g of a white powdery solid of Diblock Copolymer (1).

Next, 252 g of the obtained Diblock Copolymer (1) was dissolved in 1,600.6 g of THF and was injected into a 5-L reaction vessel, 882 g of methanol and 5.04 g of oxalic acid were then added thereto, and a deprotection reaction was performed in a nitrogen atmosphere at 40° C. for 20 hours. Next, the reaction solution was cooled to near room temperature, and 10.1 g of pyridine was then added thereto to perform a neutralization reaction. Next, the obtained deprotection reaction solution was concentrated under reduced pressure, and 1,180 g of acetone was then injected thereinto to redissolve Diblock Copolymer (2) subjected to deprotection. Next, the solution of Diblock Copolymer (2) subjected to deprotection was added to 18.5 L of ultrapure water, and Diblock Copolymer (2) was precipitated and washed. Next, the solid component was filtered out with a filter and was then dried under reduced pressure at 50° C. for 20 hours to obtain 157.1 g of a white powdery solid of Diblock Copolymer (2).

Using the obtained Diblock Copolymer (2), the composition ratio, the Mn, the PDI, and the SAXS of Diblock Copolymer (2) were measured similarly to the manner in the first example. The measurement results are described below and are listed in the following Table 2:
Composition ratio of Diblock Copolymer (2)
   4-hydroxy styrene: 4-trimethylsilyl styrene=43.0:57.0
Mn=4,000 g/mol
PDI=1.05
SAXS: no microscopic phase separation structure was observed.

| | | Mn | | hp |
|---|---|---|---|---|
| | Composition of copolymer | (g/mol) | PDI | (nm) |
| First | Tetrablock Copolymer (2) | 13,000 | 1.14 | 5.9 |
| Example | P(HSt-b-TMSSt-b-HSt-b-TMSSt | | | |
| | Composition ratio: HSt:TMSSt = | | | |
| | 50:50 | | | |
| Second | Triblock Copolymer (2) | 7,000 | 1.11 | 5.1 |
| Example | P(HSt-b-TMSSt-b-HSt) | | | |
| | Composition ratio: HSt:TMSSt = | | | |
| | 50:50 | | | |
| First | Diblock Copolymer (2) | 4,000 | 1.05 | — |
| Comparative | P(HSt-b-TMSSSt) | | | |
| Example | Composition ratio: HSt:TMSSt = | | | |
| | 43.0:57.0 | | | |

In Table 2, P represents a polymer, HSt represents 4-hydroxy styrene, and TMSSt represents 4-trimethylsilyl styrene. The symbol -b- indicates being bonded with a block chain.

As can be seen from Table 2, the multi-block copolymer of the triblock copolymer or more containing the first polymer block containing the structural unit of the specific structure and the second polymer block containing the structural unit of the specific structure, the first polymer block and the second polymer block being coupled with each other, can easily obtain the microscopic phase separation structure with a half pattern (hp) of 10 nm or smaller (the first and the second examples). It can be seen from this result that the present invention can reduce the defects resulting from the faulty microscopic phase separation sites and can besides form the fine, minute repeated pattern. In contrast, it can be seen that no microscopic phase separation structure is observed in the case of the diblock copolymer having the same structural unit as those of the first and the second examples. This result is considered to be attributed to a shortened block chain length, which did not cause the microscopic phase separation structure because of not being the multi-block copolymer of the triblock copolymer or more containing the first polymer block and the second polymer block containing the structural units of the specific structures that are coupled with each other.

### REFERENCE SIGNS LIST

1A Spherical structure
1B Cylinder structure
1C Gyroid structure
1D Lamellar structure
11, 11-1 First polymer block
12, 12-1 Second polymer block
13 Third polymer block
14 Interface

1. A polymer material for self-assembly, the polymer material comprising a multi-block copolymer of a triblock copolymer or more containing a first polymer block containing a structural unit represented by the following General Formula (1) and a second polymer block containing a structural unit represented by the following General Formula (2), the first polymer block and the second polymer block being coupled with each other: 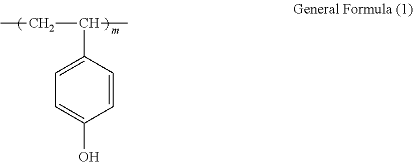
(in General Formula (1), m is an integer of 1 or larger and 1,000 or smaller); and 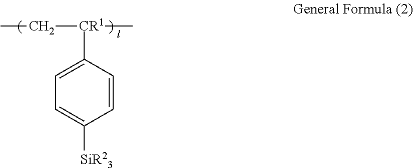
(in General Formula (2), R¹ represents a hydrogen atom and a C₁₋₃ alkyl group, R²s each represent a C₁₋₅ alkyl group; and l is an integer of 1 or larger and 1,000 or smaller).

2. The polymer material for self-assembly according to claim 1, wherein the multi-block copolymer is a triblock copolymer or a tetrablock copolymer.

3. The polymer material for self-assembly according to claim 1, wherein the multi-block copolymer is a tetrablock copolymer.

4. The polymer material for self-assembly according to claim 1, wherein the multi-block copolymer is copolymerized by living anionic polymerization.

5. The polymer material for self-assembly according to claim 1, wherein the multi-block copolymer has a number average molecular weight of 3,000 or higher and 50,000 or lower.

6. A self-assembled film obtained by using the polymer material for self-assembly according to claim 1.

7. The self-assembled film according to claim 6, wherein a top coating agent is applied onto a surface thereof.

8. A method for producing a self-assembled film, the method comprising forming a self-assembled film using the polymer material for self-assembly according to claim 1.

9. The method for producing a self-assembled film according to claim 8, wherein the self-assembled film is formed within a guide pattern.

10. The method for producing a self-assembled film according to claim 8, further comprising applying a top coating agent onto the self-assembled film.

11. A pattern formed by etching the self-assembled film according to claim 6.

12. A method for forming a pattern, the method comprising forming a pattern by etching the self-assembled film according to claim 6.
